(19) United States
(12) Patent Application Publication
(10) Pub. No.: US 2026/0187301 A1
(43) Pub. Date: Jul. 2, 2026

(54) OPTIMIZED DESIGN AND GENERATION OF A 3D PHYSICAL PROTOTYPE OF A VEHICLE

(71) Applicant: INTERNATIONAL BUSINESS MACHINES CORPORATION, ARMONK, NY (US)

(72) Inventors: Sarbajit Kumar Rakshit, Kolkata (IN); Tiberiu Suto, Franklin, NY (US); Jessica Nahulan, Vaughan (CA)

(21) Appl. No.: 18/985,132

(22) Filed: Dec. 31, 2024

(51) Int. Cl. G06F 30/15; G06F 30/27

(52) U.S. Cl. CPC G06F 30/15; G06F 30/27

(57) ABSTRACT

An approach is provided for a generative artificial intelligence (GenAI)-based optimization of a design and generation of a three-dimensional (3D) physical prototype of a vehicle. Historical data about designs of vehicles is identified. The historical data includes performance metrics and design parameters for digital and physical prototypes of the vehicles. An optimal distribution between using a digital prototyping and a physical prototyping for a design of a vehicle is determined by analyzing the identified historical data. The optimal distribution is based on functionality testing requirements for the design of the vehicle. Using a GenAI system trained on the historical data, a 3D physical prototype of the vehicle is created based on the optimal distribution.

### BACKGROUND

The present invention relates to designing and manufacturing prototypes, and more particularly to an optimization of the design and generation of a three-dimensional (3D) physical prototype of a vehicle.

### SUMMARY

In one embodiment, the present invention provides a computer-implemented method. The method includes identifying historical data about designs of vehicles. The historical data includes performance metrics and design parameters for digital and physical prototypes of the vehicles. The method further includes determining, by a processor set, an optimal distribution between using a digital prototyping and using a physical prototyping for a design of a vehicle by analyzing the identified historical data. The optimal distribution is based on functionality testing requirements for the design of the vehicle. The method further includes creating, using a generative artificial intelligence (GenAI) system trained on the historical data, a three-dimensional (3D) physical prototype of the vehicle based on the optimal distribution.

A computer system and a computer program product corresponding to the above-summarized computer-implemented method are also described herein.

### BRIEF DESCRIPTION OF THE DRAWINGS

FIG. 1 is a block diagram of a system for a GenAI-based optimized design and generation of a 3D physical prototype of a vehicle, in accordance with embodiments of the present invention.

FIG. 2 is a block diagram of modules included in code included in the system of FIG. 1, in accordance with embodiments of the present invention.

FIG. 3 is a flowchart of a process of GenAI-based optimized design and generation of a 3D physical prototype of a vehicle, where operations of the flowchart are performed by modules in FIG. 2, in accordance with embodiments of the present invention.

FIG. 4 is a block diagram of a system that performs the operations in the flowchart of FIG. 3, in accordance with embodiments of the present invention.

FIG. 5 is an example of generating a 3D physical prototype of a vehicle using the process of FIG. 3, in accordance with embodiments of the present invention.

### DETAILED DESCRIPTION

### Overview

Prototyping for vehicles includes physical, digital (i.e., virtual), and hybrid prototyping. Physical prototyping of vehicles includes the manufacture of tangible models if the vehicles, either in scaled down or actual vehicle dimensions. Manufacturing a physical prototype for a vehicle incurs additional costs and time in conventional design processes. The costs for physical prototyping can be significant, especially when executed on a large scale. Digital prototyping for vehicles employs digital tools (e.g., computer-aided design software) to provide 3D modelling and simulation. Digital prototyping offers an approach that is faster and more cost-effective than physical prototyping, but the effectiveness of digital prototyping is limited by the precision of numerical models and simulations. Hybrid prototyping for a vehicle combines a physical model with computer simulation to examine components of the vehicle in detail. Hybrid prototyping can be limited by managerial difficulties.

While both physical and digital prototypes are required for the design of vehicles, different features and functionalities of vehicles are currently tested with physical prototypes. In conventional design approaches, the design of the physical prototype is not optimized for cost and time.

Embodiments of the present invention address the aforementioned unique challenges by using generative AI to optimize the design of a 3D physical prototype of a vehicle. By considering factors such as vehicle design, testing requirements, prototyping purposes, manufacturing methods, and specifications, embodiments of the present invention provide an efficient creation of 3D models, thereby reducing costs and streamlining the 3D model design process.

In one embodiment, the optimized design and generation of 3D models of vehicles includes (i) identifying historical data relevant to vehicle design, including performance metrics and design parameters for digital and physical prototypes; (ii) analyzing the historical data to determine optimal distribution between digital simulation and physical prototyping phases based on functionality testing requirements for the vehicle design; (iii) employing GenAI to dynamically design both digital and physical prototypes with specifications optimized for functionality testing and manufacturing efficiency; (iv) evaluating influencing factors, such as weight, internal structure, material types, and surface finish, to determine specifications for a 3D prototype; (v) utilizing GenAI to generate a 3D model of the prototype, considering selected manufacturing methods, such as material cutting, 3D printing, and/or casting, to optimize manufacturing time and material usage; and (vi) designing a 3D model of the prototype based on criteria, including minimizing manufacturing time, reducing material costs, optimizing weight distribution, and adjusting the center of gravity as required.

### Computing Environment

Various aspects of the present disclosure are described by narrative text, flowcharts, block diagrams of computer systems and/or block diagrams of the machine logic included in computer program product (CPP) embodiments. With respect to any flowcharts, depending upon the technology involved, the operations can be performed in a different order than what is shown in a given flowchart. For example, again depending upon the technology involved, two operations shown in successive flowchart blocks may be performed in reverse order, as a single integrated step, concurrently, or in a manner at least partially overlapping in time.

A computer program product embodiment (“CPP embodiment” or “CPP”) is a term used in the present disclosure to describe any set of one, or more, computer-readable storage media (also called “mediums”) collectively included in a set of one, or more, storage devices, and that collectively include machine readable code corresponding to instructions and/or data for performing computer operations specified in a given CPP claim. A “storage device” is any tangible device that can retain and store instructions for use by a computer processor. Without limitation, the computer-readable storage medium may be an electronic storage medium, a magnetic storage medium, an optical storage medium, an electromagnetic storage medium, a semiconductor storage medium, a mechanical storage medium, or any suitable combination of the foregoing. Some known types of storage devices that include these mediums include: diskette, hard disk, random access memory (RAM), read-only memory (ROM), erasable programmable read-only memory (EPROM or Flash memory), static random access memory (SRAM), compact disc read-only memory (CD-ROM), digital versatile disk (DVD), memory stick, floppy disk, mechanically encoded device (such as punch cards or pits/lands formed in a major surface of a disc) or any suitable combination of the foregoing. A computer-readable storage medium, as that term is used in the present disclosure, is not to be construed as storage in the form of transitory signals per se, such as radio waves or other freely propagating electromagnetic waves, electromagnetic waves propagating through a waveguide, light pulses passing through a fiber optic cable, electrical signals communicated through a wire, and/or other transmission media. As will be understood by those of skill in the art, data is typically moved at some occasional points in time during normal operations of a storage device, such as during access, de-fragmentation or garbage collection, but this does not render the storage device as transitory because the data is not transitory while it is stored.

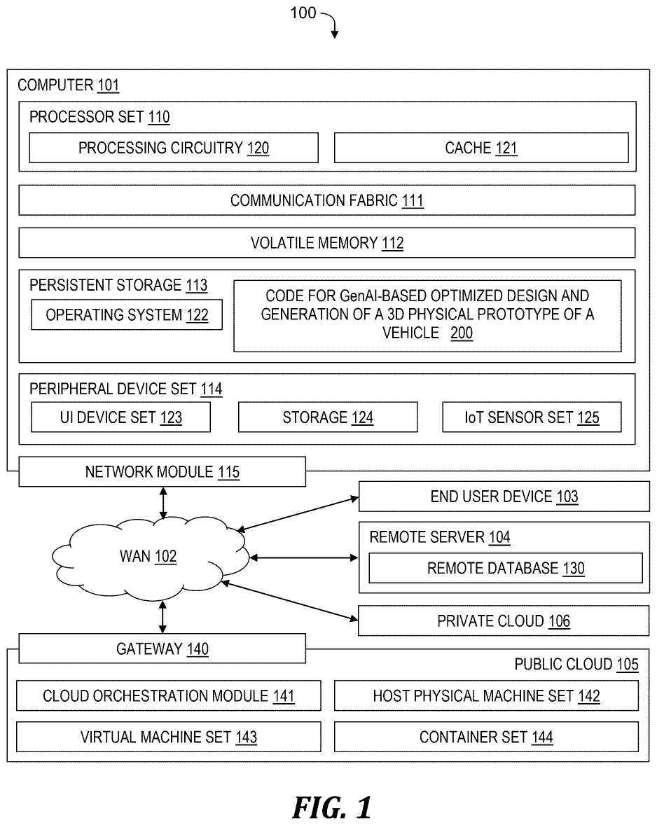

FIG. 1 is a block diagram of a system for a GenAI-based optimized design and generation of a 3D physical prototype of a vehicle, in accordance with embodiments of the present invention. Computing environment 100 contains an example of an environment for the execution of at least some of the computer code involved in performing the inventive methods, such as code 200 for GenAI-based optimized design and generation of a 3D physical prototype of a vehicle. The aforementioned computer code is also referred to herein as computer-readable code, computer-readable program code, and machine readable code. In addition to block 200, computing environment 100 includes, for example, computer 101, wide area network (WAN) 102, end user device (EUD) 103, remote server 104, public cloud 105, and private cloud 106. In this embodiment, computer 101 includes processor set 110 (including processing circuitry 120 and cache 121), communication fabric 111, volatile memory 112, persistent storage 113 (including operating system 122 and block 200, as identified above), peripheral device set 114 (including user interface (UI) device set 123, storage 124, and Internet of Things (IoT) sensor set 125), and network module 115. Remote server 104 includes remote database 130. Public cloud 105 includes gateway 140, cloud orchestration module 141, host physical machine set 142, virtual machine set 143, and container set 144.

COMPUTER 101 may take the form of a desktop computer, laptop computer, tablet computer, smart phone, smart watch or other wearable computer, mainframe computer, quantum computer or any other form of computer or mobile device now known or to be developed in the future that is capable of running a program, accessing a network or querying a database, such as remote database 130. As is well understood in the art of computer technology, and depending upon the technology, performance of a computer-implemented method may be distributed among multiple computers and/or between multiple locations. On the other hand, in this presentation of computing environment 100, detailed discussion is focused on a single computer, specifically computer 101, to keep the presentation as simple as possible. Computer 101 may be located in a cloud, even though it is not shown in a cloud in FIG. 1. On the other hand, computer 101 is not required to be in a cloud except to any extent as may be affirmatively indicated.

PROCESSOR SET 110 includes one, or more, computer processors of any type now known or to be developed in the future. Processing circuitry 120 may be distributed over multiple packages, for example, multiple, coordinated integrated circuit chips. Processing circuitry 120 may implement multiple processor threads and/or multiple processor cores. Cache 121 is memory that is located in the processor chip package(s) and is typically used for data or code that should be available for rapid access by the threads or cores running on processor set 110. Cache memories are typically organized into multiple levels depending upon relative proximity to the processing circuitry. Alternatively, some, or all, of the cache for the processor set may be located “off chip.” In some computing environments, processor set 110 may be designed for working with qubits and performing quantum computing.

Computer-readable program instructions are typically loaded onto computer 101 to cause a series of operational steps to be performed by processor set 110 of computer 101 and thereby effect a computer-implemented method, such that the instructions thus executed will instantiate the methods specified in flowcharts and/or narrative descriptions of computer-implemented methods included in this document (collectively referred to as “the inventive methods”). These computer-readable program instructions are stored in various types of computer-readable storage media, such as cache 121 and the other storage media discussed below. The program instructions, and associated data, are accessed by processor set 110 to control and direct performance of the inventive methods. In computing environment 100, at least some of the instructions for performing the inventive methods may be stored in block 200 in persistent storage 113.

COMMUNICATION FABRIC 111 is the signal conduction path that allows the various components of computer 101 to communicate with each other. Typically, this fabric is made of switches and electrically conductive paths, such as the switches and electrically conductive paths that make up busses, bridges, physical input/output ports and the like. Other types of signal communication paths may be used, such as fiber optic communication paths and/or wireless communication paths.

VOLATILE MEMORY 112 is any type of volatile memory now known or to be developed in the future. Examples include dynamic type random access memory (RAM) or static type RAM. Typically, volatile memory 112 is characterized by random access, but this is not required unless affirmatively indicated. In computer 101, the volatile memory 112 is located in a single package and is internal to computer 101, but, alternatively or additionally, the volatile memory may be distributed over multiple packages and/or located externally with respect to computer 101.

PERSISTENT STORAGE 113 is any form of non-volatile storage for computers that is now known or to be developed in the future. The non-volatility of this storage means that the stored data is maintained regardless of whether power is being supplied to computer 101 and/or directly to persistent storage 113. Persistent storage 113 may be a read only memory (ROM), but typically at least a portion of the persistent storage allows writing of data, deletion of data and re-writing of data. Some familiar forms of persistent storage include magnetic disks and solid state storage devices. Operating system 122 may take several forms, such as various known proprietary operating systems or open source Portable Operating System Interface-type operating systems that employ a kernel. The code included in block 200 typically includes at least some of the computer code involved in performing the inventive methods.

PERIPHERAL DEVICE SET 114 includes the set of peripheral devices of computer 101. Data communication connections between the peripheral devices and the other components of computer 101 may be implemented in various ways, such as Bluetooth connections, Near-Field Communication (NFC) connections, connections made by cables (such as universal serial bus (USB) type cables), insertion-type connections (for example, secure digital (SD) card), connections made through local area communication networks and even connections made through wide area networks such as the internet. In various embodiments, UI device set 123 may include components such as a display screen, speaker, microphone, wearable devices (such as goggles and smart watches), keyboard, mouse, printer, touchpad, game controllers, and haptic devices. Storage 124 is external storage, such as an external hard drive, or insertable storage, such as an SD card. Storage 124 may be persistent and/or volatile. In some embodiments, storage 124 may take the form of a quantum computing storage device for storing data in the form of qubits. In embodiments where computer 101 is required to have a large amount of storage (for example, where computer 101 locally stores and manages a large database) then this storage may be provided by peripheral storage devices designed for storing very large amounts of data, such as a storage area network (SAN) that is shared by multiple, geographically distributed computers. IoT sensor set 125 is made up of sensors that can be used in Internet of Things applications. For example, one sensor may be a thermometer and another sensor may be a motion detector.

NETWORK MODULE 115 is the collection of computer software, hardware, and firmware that allows computer 101 to communicate with other computers through WAN 102. Network module 115 may include hardware, such as modems or Wi-Fi signal transceivers, software for packetizing and/or de-packetizing data for communication network transmission, and/or web browser software for communicating data over the internet. In some embodiments, network control functions and network forwarding functions of network module 115 are performed on the same physical hardware device. In other embodiments (for example, embodiments that utilize software-defined networking (SDN)), the control functions and the forwarding functions of network module 115 are performed on physically separate devices, such that the control functions manage several different network hardware devices. Computer-readable program instructions for performing the inventive methods can typically be downloaded to computer 101 from an external computer or external storage device through a network adapter card or network interface included in network module 115.

WAN 102 is any wide area network (for example, the internet) capable of communicating computer data over non-local distances by any technology for communicating computer data, now known or to be developed in the future. In some embodiments, the WAN 102 may be replaced and/or supplemented by local area networks (LANs) designed to communicate data between devices located in a local area, such as a Wi-Fi network. The WAN and/or LANs typically include computer hardware such as copper transmission cables, optical transmission fibers, wireless transmission, routers, firewalls, switches, gateway computers and edge servers.

END USER DEVICE (EUD) 103 is any computer system that is used and controlled by an end user (for example, a customer of an enterprise that operates computer 101), and may take any of the forms discussed above in connection with computer 101. EUD 103 typically receives helpful and useful data from the operations of computer 101. For example, in a hypothetical case where computer 101 is designed to provide a recommendation to an end user, this recommendation would typically be communicated from network module 115 of computer 101 through WAN 102 to EUD 103. In this way, EUD 103 can display, or otherwise present, the recommendation to an end user. In some embodiments, EUD 103 may be a client device, such as thin client, heavy client, mainframe computer, desktop computer and so on.

REMOTE SERVER 104 is any computer system that serves at least some data and/or functionality to computer 101. Remote server 104 may be controlled and used by the same entity that operates computer 101. Remote server 104 represents the machine(s) that collect and store helpful and useful data for use by other computers, such as computer 101. For example, in a hypothetical case where computer 101 is designed and programmed to provide a recommendation based on historical data, then this historical data may be provided to computer 101 from remote database 130 of remote server 104.

PUBLIC CLOUD 105 is any computer system available for use by multiple entities that provides on-demand availability of computer system resources and/or other computer capabilities, especially data storage (cloud storage) and computing power, without direct active management by the user. Cloud computing typically leverages sharing of resources to achieve coherence and economies of scale. The direct and active management of the computing resources of public cloud 105 is performed by the computer hardware and/or software of cloud orchestration module 141. The computing resources provided by public cloud 105 are typically implemented by virtual computing environments that run on various computers making up the computers of host physical machine set 142, which is the universe of physical computers in and/or available to public cloud 105. The virtual computing environments (VCEs) typically take the form of virtual machines from virtual machine set 143 and/or containers from container set 144. It is understood that these VCEs may be stored as images and may be transferred among and between the various physical machine hosts, either as images or after instantiation of the VCE. Cloud orchestration module 141 manages the transfer and storage of images, deploys new instantiations of VCEs and manages active instantiations of VCE deployments. Gateway 140 is the collection of computer software, hardware, and firmware that allows public cloud 105 to communicate through WAN 102.

Some further explanation of virtualized computing environments (VCEs) will now be provided. VCEs can be stored as “images.” A new active instance of the VCE can be instantiated from the image. Two familiar types of VCEs are virtual machines and containers. A container is a VCE that uses operating-system-level virtualization. This refers to an operating system feature in which the kernel allows the existence of multiple isolated user-space instances, called containers. These isolated user-space instances typically behave as real computers from the point of view of programs running in them. A computer program running on an ordinary operating system can utilize all resources of that computer, such as connected devices, files and folders, network shares, CPU power, and quantifiable hardware capabilities. However, programs running inside a container can only use the contents of the container and devices assigned to the container, a feature which is known as containerization.

PRIVATE CLOUD 106 is similar to public cloud 105, except that the computing resources are only available for use by a single enterprise. While private cloud 106 is depicted as being in communication with WAN 102, in other embodiments a private cloud may be disconnected from the internet entirely and only accessible through a local/private network. A hybrid cloud is a composition of multiple clouds of different types (for example, private, community or public cloud types), often respectively implemented by different vendors. Each of the multiple clouds remains a separate and discrete entity, but the larger hybrid cloud architecture is bound together by standardized or proprietary technology that enables orchestration, management, and/or data/application portability between the multiple constituent clouds. In this embodiment, public cloud 105 and private cloud 106 are both part of a larger hybrid cloud.

CLOUD COMPUTING SERVICES AND/OR MICROSERVICES (not Separately Shown in FIG. 1): private and public clouds 106 are programmed and configured to deliver cloud computing services and/or microservices (unless otherwise indicated, the word “microservices” shall be interpreted as inclusive of larger “services” regardless of size). Cloud services are infrastructure, platforms, or software that are typically hosted by third-party providers and made available to users through the internet. Cloud services facilitate the flow of user data from front-end clients (for example, user-side servers, tablets, desktops, laptops), through the internet, to the provider's systems, and back. In some embodiments, cloud services may be configured and orchestrated according to an “as a service” technology paradigm where something is being presented to an internal or external customer in the form of a cloud computing service. As-a-Service offerings typically provide endpoints with which various customers interface. These endpoints are typically based on a set of APIs. One category of as-a-service offering is Platform as a Service (PaaS), where a service provider provisions, instantiates, runs, and manages a modular bundle of code that customers can use to instantiate a computing platform and one or more applications, without the complexity of building and maintaining the infrastructure typically associated with these things. Another category is Software as a Service (SaaS) where software is centrally hosted and allocated on a subscription basis. SaaS is also known as on-demand software, web-based software, or web-hosted software. Four technological sub-fields involved in cloud services are: deployment, integration, on demand, and virtual private networks.

### System and Process for an Optimized Design and Generation of a 3D Physical Prototype of a Vehicle

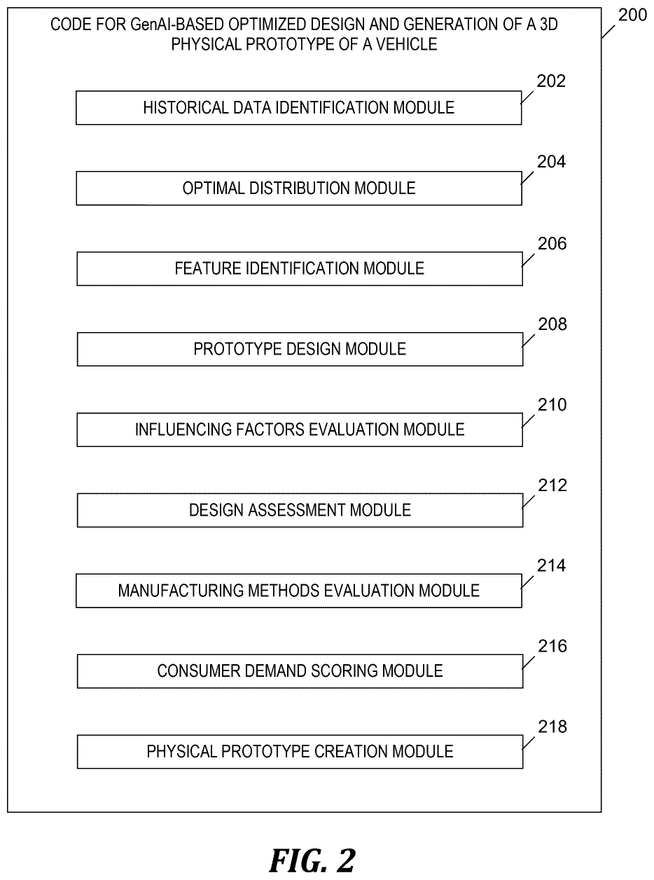

FIG. 2 is a block diagram of modules included in code 200 included in the system of FIG. 1, in accordance with embodiments of the present invention. Code 200 includes a historical data identification module 202, an optimal distribution module 204, a feature identification module 206, a prototype design module 208, an influencing factors evaluation module 210, a design assessment module 212, a manufacturing methods evaluation module 214, and a physical prototype creation module 216.

Historical data identification module 202 is configured to identify historical data relevant to vehicle design, where the historical data includes performance metrics and design parameters for digital and physical prototypes. Historical data identification module 202 is also configured to analyze the design of vehicles using the identified historical data, where the design includes specifications and functionalities of vehicles.

Optimal distribution module 204 is configured to use historical learning to determine an optimal distribution between digital simulation and physical prototyping phases by analyzing the historical data identified by historical data identification module 202 to determine what distributions between digital and physical prototyping have achieved successful vehicle testing in the past, and/or to determine what distribution minimizes the cost of manufacturing 3D models for the physical prototyping. In one embodiment, the optimal distribution is based on functionality testing requirements for the design of the vehicle. Optimal distribution module 204 is also configured to determine each functionality of the vehicle that is to be tested with both a digital prototype and a physical prototype of the vehicle.

Feature identification module 206 is configured to determine one or more features or capabilities of the vehicle that are to be tested using a 3D physical prototype of the vehicle. Feature identification module 206 is also configured to determine which other features of the vehicle are not to be considered in the testing that uses the 3D physical prototype.

In one embodiment, feature identification module 206 uses the historical data collected by historical data identification module 202 to identify types of vehicle features and capabilities that require testing with (i) a digital prototype only, (ii) a physical prototype only, and (iii) both a digital prototype and a physical prototype.

Prototype design module 208 is configured to employ GenAI to dynamically design digital and physical prototypes based on specifications that are optimized for functionality testing and manufacturing efficiency and cost.

Influencing factors evaluation module 210 is configured to use GenAI to identify and evaluate influencing factors associated with the physical prototype, where the influencing factors include weight, internal structure (e.g., hollow or solid prototype), material types, surface finish, and portions of the vehicle that do not require prototyping. In one embodiment, influencing factors evaluation module 210 receives the influencing factors as input provided by manufacturers or other end users of the system that provides the GenAI-based optimized design and generation of 3D physical prototypes of vehicles. In another embodiment, influencing factors evaluation module 210 retrieves the influencing factors from a data repository.

Influencing factors evaluation module 210 is also configured to determine specifications for a 3D physical prototype based on the evaluated influencing factors, where the specifications achieve optimal material usage and manufacturing time efficiency during the manufacturing of the 3D physical prototype. In one embodiment, prototype design module 208 uses GenAI to design the 3D physical prototype based on the aforementioned specifications so that optimal material usage and manufacturing time efficiency is achieved during the manufacture of the 3D physical prototype.

Design assessment module 212 is configured to assess the design of the vehicle and based on the assessment, determine design criteria for the 3D physical prototype. In one embodiment, the design criteria include any combination of the following: minimizing the manufacturing time of the 3D physical prototype, minimizing material costs for the 3D physical prototype, optimizing weight distribution of the 3D physical prototype, and adjusting the center of gravity (CG) of the 3D physical prototype. In one embodiment, prototype design module 208 uses GenAI to design the 3D physical prototype based on the aforementioned design criteria.

Manufacturing methods evaluation module 214 is configured to evaluate different types of manufacturing methods for producing the 3D physical prototype, including material cutting, 3D printing, and casting, and to select one of the types of manufacturing methods for producing the 3D physical prototype based on the evaluation of the types. In one embodiment, prototype design module 208 uses GenAI to design the 3D physical prototype based on the selected manufacturing method and the specifications determined based on the evaluated influencing factors.

Consumer demand scoring module 216 is configured to receive consumer feedback about potential designs of the vehicle after identifying manufacture-feasible options for the vehicle. For example, consumer demand scoring module 216 posts the manufacture-feasible options online to request and collect consumer feedback about the options based on consumer opt-in for the collection of the feedback. The consumer feedback includes, for example, parts of a design of the vehicle a given consumer finds attractive or unattractive and design choices that influence the given consumer to purchase or to not purchase the vehicle. In one embodiment, consumer demand scoring module 216 is further configured to determine functionality importance scores of various features that can be added to the vehicle to fulfill a given consumer's use cases.

In one embodiment, consumer demand scoring module 216 is further configured to generate a digital twin representation of a given consumer and the consumer's family in response to receiving consent from the consumer. The digital twin representation can be used by the consumer to visualize particular design constraints of the vehicle for the consumer's use case. For example, if the digital twin of a given consumer is 6 feet, 4 inches tall, the visualization indicates that the headroom available for the consumer is sufficient if the consumer is sitting in the front seat, but is not sufficient if the consumer is sitting in the middle or back seat (e.g., when sitting in the back seat, the consumer's head reaches the ceiling of the vehicle, thereby making the fit in the back seat uncomfortable).

The digital twin representation provided by consumer demand scoring module 216 can also include climate control preferences. For example, one household member may prefer a setting of 68 degrees for climate control, while another household member may prefer 75 degrees. For some vehicle designs with separate climate controls, the aforementioned difference in temperature preferences can be accommodated, while for other vehicle designs, the temperature difference may be too great to accurately deliver the desired climate control settings.

With consumer opt-in, consumer demand scoring module 216 allows the manufacturer to collect anonymized consumer digital twin information in order to determine the number of consumers impacted by various design choices. Additional crowdsourced data may be infused from social media comments about proposed design elements.

After collecting the aforementioned consumer feedback and/or digital twin information, consumer demand scoring module 216 tags all potential design changes or updates with a cost to implement that change or update in the vehicle. Consumer demand scoring module 216 analyzes (i) the numbers of consumers that are affected by each potential design change or update, (ii) the cost of each potential design change or update, and (iii) the return on investment (ROI) of implementing the change or update. Consumer demand scoring module 216 determines which changes or updates result in positive cash flow to the manufacturer to implement in the long run, and which changes or updates will generate the most consumer demand. In one embodiment, prototype design module 208 uses the results of the consumer demand analysis performed by consumer demand scoring module 216 to design the 3D physical prototype.

Physical prototype creation module 218 is configured to produce the 3D physical prototype of the vehicle with an optimal manufacturing cost and time, based on any combination of the following: (i) the features and capabilities identified by feature identification module 206, (ii) the influencing factors identified and evaluated by influencing factors evaluation module 210, (iii) the manufacturing method selected by manufacturing methods evaluation module 214, (iv) the design criteria determined by design assessment module 212, and (v) the consumer demand and functionality importance scores determined and analyzed by consumer demand scoring module 216.

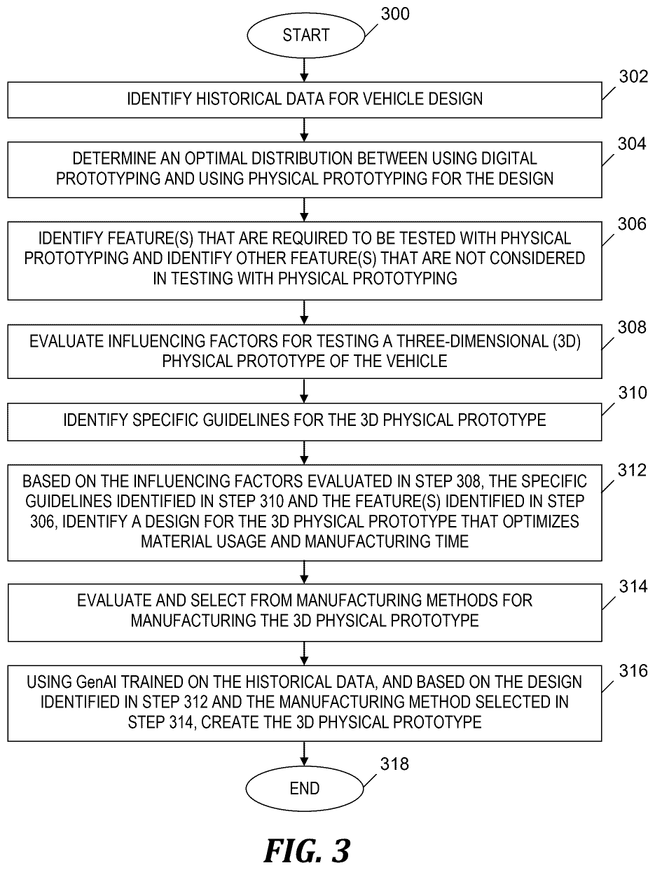

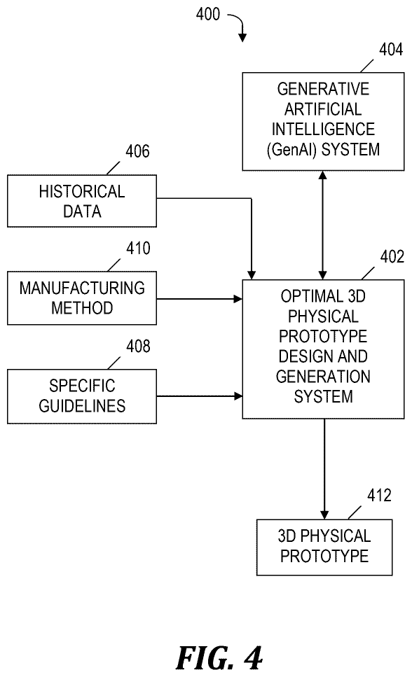

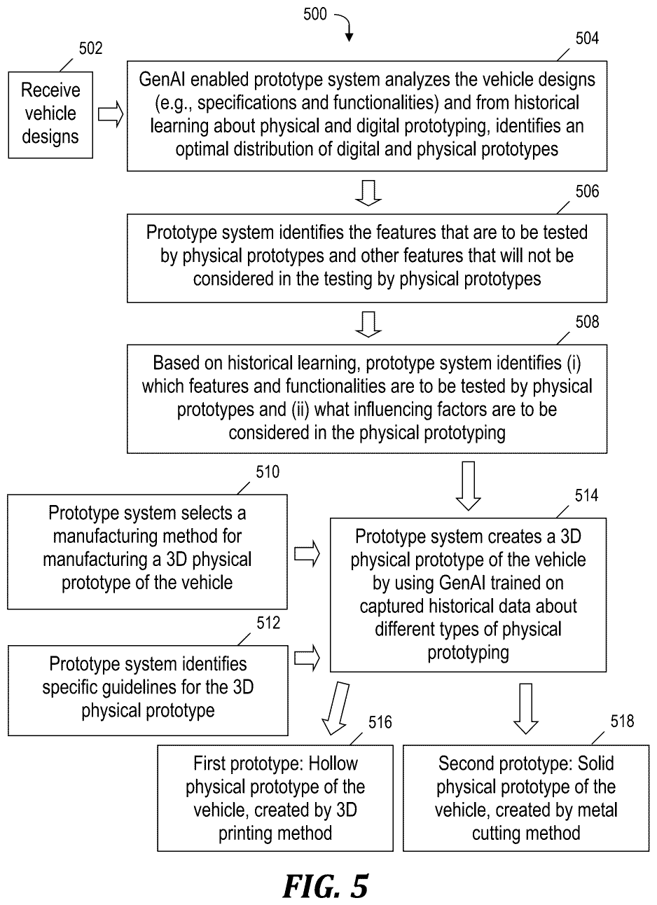

The functionality of the modules included in code 200 is described in more detail in the discussions presented below relative to FIG. 3, FIG. 4, and FIG. 5.

FIG. 3 is a flowchart of a process of GenAI-based optimized design and generation of a 3D physical prototype of a vehicle, where operations of the flowchart are performed by modules in FIG. 2, in accordance with embodiments of the present invention. The process of FIG. 3 begins at a start node 300. In step 302, historical data identification module 202 identifies and collects historical data for multiple designs of multiple types of vehicles. In one embodiment, step 302 includes historical data identification module 202 collecting historical data related to different types of simulations, including a digital twin simulation with a digital prototype.

In step 304, based on the aforementioned collected historical data, optimal distribution module 204 identifies (i) first types of vehicle features and capabilities that require testing with a digital prototype only, (ii) second types of vehicle features and capabilities that require testing with a physical prototype only, and (iii) third types of vehicle features and capabilities, where each of the third types require testing with both a digital prototype and a physical prototype. Furthermore, in step 304, optimal distribution module 204 determines an optimal distribution between using digital prototyping and using physical prototyping for the design of a vehicle, where the determination of the optimal distribution is based on the historical data collected by historical data identification module 202. In one embodiment, the determination of the optimal distribution between digital and physical prototyping by the optimal distribution module 204 is further based on the visual design of the vehicle, which can include the shape and surface profile of the vehicle, and can further include design elements of the interior or exterior of the vehicle.

In one embodiment, the system providing the GenAI-based optimized design and generation of a 3D physical prototype captures historical data about vehicle design and trains a machine learning model to identify patterns and correlations between vehicle design decisions, testing requirements, and the performance of both digital and physical prototypes. The determination of the optimal distribution between digital and physical prototyping in step 304 is further based on the patterns and correlations identified by the aforementioned machine learning model.

In one embodiment, the optimal distribution determined in step 304 is further based on the shape and/or dimensions of the vehicle.

In one embodiment, the optimal distribution determined in step 304 is further based on the features and capabilities of the vehicle that are tested, the portions of the vehicle that include those features and capabilities, and a mapping of those features and capabilities to the bill of material required to assemble the physical prototype.

In one embodiment, the system providing the GenAI-based optimized design and generation of a 3D physical prototype analyzes the design of the vehicle, including the shape, dimensions, and specifications of the vehicle, and captures the bill of materials for the physical prototype, and the optimal distribution determined in step 304 is further based on the analysis of the design and the captured bill of materials.

In one embodiment, the system providing the GenAI-based optimized design and generation of a 3D physical prototype employs historical learning using a machine learning model to analyze the design of the vehicle and to identify different vehicle functionalities that require both digital and physical prototyping, where the determination of the optimal distribution in step 304 is further based on the machine learning model analysis of the design and the identified vehicle functionalities that require both digital and physical prototyping.

In step 306, feature identification module 206 identifies one or more features and/or one or more capabilities of the vehicle that are required to be tested by using a physical prototype, and identifies other features and/or capabilities of the vehicle that are not considered in testing using physical prototyping. In one embodiment, based on design objectives and performance criteria of the vehicle, and based on any specific requirements for the vehicle (e.g., aerodynamics, fuel efficiency, safety standards, material considerations, balancing, etc.), feature identification module 206 uses an artificial intelligence (AI) system to identify critical features of the vehicle that require testing and validation through physical prototypes, where the critical features can be, for example, aerodynamic shapes or material properties.

In one embodiment, feature identification module 206 uses historical learning to identify the bill of materials required for the physical prototype of the vehicle and maps the identified features and capabilities to the bill of materials.

In one embodiment, feature identification module 206 generates a list of physical and digital prototypes along with associated testing requirements and any vehicle features which led to a prototype being identified as requiring a physical construction. Feature identification module 206 presents the aforementioned generated list to an end user, who provides final approval or an alteration of the list.

In step 308, influencing factors evaluation module 210 identifies influencing factors for testing of the physical prototype of the vehicle, such as weather conditions, wind flow, temperature, jerking, and road profile. In one embodiment, influencing factors evaluation module 210 receives the influencing factors via historical learning or manual user input. In one embodiment, influencing factors evaluation module 210 identifies the bill of materials required by the physical prototype based at least in part on the identified influencing factors.

In step 310, influencing factors evaluation module 210 identifies specific guidelines for manufacturing the physical prototype of the vehicle, where the specific guidelines are based on the feature(s) identified in step 306. In one embodiment, the specific guidelines are a manufacturer's preferences related to the manufacturing of the 3D physical prototype. In one embodiment, the identification of the specific guidelines is based on historical learning that uses the historical data identified in step 302. In one embodiment, the specific guidelines include weight constraints and types of material for the manufacture of the physical prototype. The specific guidelines do not include a selection of a manufacturing method, which is addressed in step 314, as discussed below.

In step 312, based on the influencing factors evaluated in step 308, the specific guidelines identified in step 310, and the feature(s) identified in step 306, design assessment module 212 uses a GenAI system to identify a design for the physical prototype that optimizes material usage and manufacturing time in the manufacturing of the physical prototype.

In one embodiment, step 312 includes design assessment module 212 identifying multiple tentative designs for the vehicle based on the influencing factors, the specific guidelines and the identified features, and subsequently selecting one of the tentative designs as a final design based on a cost-benefit analysis of the tentative designs.

In step 314, manufacturing methods evaluation module 214 evaluates multiple manufacturing methods for manufacturing the physical prototype, and based on the evaluation, manufacturing methods evaluation module 214 selects a manufacturing method from the multiple manufacturing methods to be used for manufacturing the physical prototype. Manufacturing methods evaluation module 214 also identifies the types of objects that can be manufactured with the different manufacturing methods.

The evaluation of the manufacturing methods in step 314 includes determining which manufacturing methods have a capability or a difficulty in manufacturing the physical prototype. For example, a material cutting method has difficulty or is a time consuming method for creating a hollow structure in a physical prototype, while a 3D printing method overcomes the difficulties of the material cutting method and can effectively create the hollow structure.

The evaluation of manufacturing methods in step 314 includes evaluating different capabilities and key performance indicators of the manufacturing methods, including manufacturing time, cost of manufacturing, material usage, and wastage.

In cases of limited high quality material (e.g., certain filaments) for use in the manufacturing of the physical prototype, manufacturing methods evaluation module 214 prioritizes material usage on physical prototypes and sections of the prototypes, by identifying which prototypes will be tested by customers or are scheduled for use in high priority meetings, as well as which prototypes have historically been the most tested and have been shown to be items of interest.

In step 316, based on the design identified in step 312 and the manufacturing method selected in step 314, physical prototype creation module 218 uses GenAI trained on the aforementioned historical data to create the physical prototype.

After step 316, the process of FIG. 3 ends at an end node 318.

In one embodiment, the system providing the GenAI-based optimized design and generation of a 3D physical prototype uses GenAI, such as a generative adversarial network (GAN), to identify an appropriate 3D model of the physical prototype, and uses GenAI algorithms to create multiple design iterations based on the identified features of the vehicle. The system trains the GenAI to understand the design constraints, manufacturing limitations, and performance requirements. The system uses GenAI to create a variety of vehicle design alternatives. In one embodiment, based on a cost-benefit analysis, the system uses Gen AI to identify an appropriate 3D model of the physical prototype.

In an alternative embodiment, the process of FIG. 3 includes consumer demand scoring module 216 receiving consumer feedback about multiple features that are specified in different designs that are candidates for being a final design of the 3D physical prototype, where the multiple features are identified by feature identification module 206. For a given design included in the different designs, demand scoring module 216 determines that the given design includes one or more features included in the aforementioned multiple features. Based on the consumer feedback, demand scoring module 216 computes one or more functionality importance scores for the aforementioned one or more features, respectively. Demand scoring module 216 determines that each of the computed one or more functionality importance scores exceeds a predetermined threshold value. Based in part on each of the computed one or more functionality importance scores exceeding the predetermined threshold value, demand scoring module 216 generates and presents a recommendation of the given design as being the final design of the 3D physical prototype. In an alternative to step 316, physical prototype creation module 218 creates the 3D physical prototype based on the feature(s) identified in step 306, the specific guidelines identified in step 310, the manufacturing method selected in step 314, and the aforementioned one or more functionality importance scores each exceeding the threshold value.

In an alternative embodiment, the process of FIG. 3 is expanded to include additional step(s) that determine a sequence of testing with multiple 3D physical prototypes, where the sequence is determined so that a first 3D physical prototype created in step 316 is later modified and re-used as a second 3D physical prototype in the sequence of testing, thereby avoiding the need to create an entirely new second 3D physical prototype from scratch, which minimizes material usage and reduces waste.

For example, if the aerodynamic feature of a car is being tested, physical prototype creation module 218 determines a sequence of physical prototyping for the car that includes a testing a first physical prototype that has more material and subsequently testing a second physical prototype that has less material. Physical prototype creation module 218 creates the first physical prototype in step 316. Subsequent to testing the aerodynamic feature of the first physical prototype, physical prototype creation module 218 shaves material off of the first physical prototype to create the second physical prototype as a modification of the first physical prototype, without having to generate the second physical prototype in its entirety.

FIG. 4 is a block diagram of a system 400 that performs operations in the flowchart of FIG. 3, in accordance with embodiments of the present invention. System 400 includes an optimal 3D physical prototype design and generation system 402, a generative AI system 404, historical data 406, specific guidelines 408, a manufacturing method 410, and a 3D physical prototype 412.

Optimal 3D physical prototype design and generation system 402 performs step 302 to use GenAI system 404 to identify historical data 406 relevant to the design of vehicles, such as performance metrics and design parameters for digital and physical prototypes. Based on historical data 406, optimal 3D physical prototype design and generation system 402 performs step 304 by using GenAI system 404 to determine an optimal distribution between using digital and physical prototyping for a design of a vehicle.

Optimal 3D physical prototype design and generation system 402 identifies features of the vehicle that are required to be tested with physical prototyping and identifies other features of the vehicle that are not considered in testing with physical prototyping, which is included in step 306.

Optimal 3D physical prototype design and generation system 402 performs step 308 to evaluate the influencing factors (not shown) for testing the physical prototype of the vehicle and performs step 310 to receive or identify specific guidelines 408 for manufacturing the physical prototype.

Optimal 3D physical prototype design and generation system 402 performs step 312 to identify a design (not shown) for the physical prototype that optimizes material usage and manufacturing time for the manufacturing of the physical prototype, where the identification of the design is based on the aforementioned influencing factors and specific guidelines 408.

Optimal 3D physical prototype design and generation system 402 evaluates multiple manufacturing methods that could be used for manufacturing the physical prototype of the vehicle. Based on the evaluation of the multiple manufacturing methods, optimal 3D physical prototype design and generation system 402 selects manufacturing method 408 as the method to be used for manufacturing the physical prototype.

Using GenAI system 404, which is trained on historical data 406, optimal 3D physical prototype design and generation system 402 creates a 3D physical prototype 412 of the vehicle, where the creation of 3D physical prototype 412 is based on the design identified in step 312 and the manufacturing method 410. In an alternate embodiment, the creation of 3D physical prototype 412 is further based on functionality importance scores determined by consumer demand scoring module 216.

### EXAMPLE

FIG. 5 is an example 500 of generating a 3D physical prototype of a vehicle using the process of FIG. 3, in accordance with embodiments of the present invention. In step 502, optimal 3D physical prototype design and generation system 402 receives vehicle designs (e.g., specifications and functionalities of vehicles).

In step 504, optimal 3D physical prototype design and generation system 402 analyzes the vehicle designs received in step 502. Using historical learning about physical and digital prototyping provided by GenAI system 404, optimal 3D physical prototype design and generation system 402 identifies an optimal distribution of digital and physical prototypes for the vehicle. In one embodiment, step 504 is included in step 304.

In step 506, optimal 3D physical prototype design and generation system 402 identifies vehicle features that are to be tested by physical prototypes and other vehicle features that will not be considered in the testing by physical prototypes. In one embodiment, step 506 is included in step 306.

In step 508, based on historical learning provided by GenAI system 404, optimal 3D physical prototype design and generation system 402 identifies which features and functionalities of the vehicle are to be tested by physical prototypes and what influencing factors are to be considered in the physical prototyping.

In step 510, optimal 3D physical prototype design and generation system 402 selects a manufacturing method 410 for manufacturing the 3D physical prototype of the vehicle. In one embodiment, step 510 is included in step 314.

In step 512, optimal 3D physical prototype design and generation system 402 receives or identifies specific guidelines 408 about the manufacturing of the 3D physical prototype. In one embodiment, step 512 is included in step 310.

In step 514, optimal 3D physical prototype design and generation system 402 creates the 3D physical prototype of the vehicle by using GenAI system 404 trained on captured historical data 406 about different types of physical prototyping, where the creation of the 3D physical prototype is based on the influencing factors identified in step 508, the features identified in step 506, the manufacturing method selected in step 510, and the specific guidelines identified in step 512. In one embodiment, the performance of step 514 results in a first prototype 516, which is a hollow 3D physical prototype of the vehicle, created by a 3D printing method selected as the manufacturing method in step 510. In another embodiment, the performance of step 514 results in a second prototype 518, which is a solid 3D physical prototype of the vehicle, created by a metal cutting methods selected as the manufacturing method in step 510.

The descriptions of the various embodiments of the present invention have been presented herein for purposes of illustration but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A computer-implemented method comprising:
identifying historical data about designs of vehicles, the historical data including performance metrics and design parameters for digital and physical prototypes of the vehicles;
determining, by a processor set, an optimal distribution between using a digital prototyping and using a physical prototyping for a design of a vehicle by analyzing the identified historical data, the optimal distribution being based on functionality testing requirements for the design of the vehicle; and
creating, using a generative artificial intelligence (GenAI) system trained on the historical data, a three-dimensional (3D) physical prototype of the vehicle based on the optimal distribution.

2. The method of claim 1, further comprising:
identifying one or more first features of the vehicle that require testing using the physical prototyping and one or more second features of the vehicle that do not require testing using the physical prototyping; and
identifying, using the GenAI system, a design of the 3D physical prototype of the vehicle based on the identified one or more first features, wherein the design optimizes a usage of material and a manufacturing time in a process of manufacturing the 3D physical prototype, and wherein the creating the 3D physical prototype of the vehicle is further based on the identified design.

3. The method of claim 2, further comprising:
evaluating influencing factors for testing the 3D physical prototype, the influencing factors including a weight of the 3D physical prototype, an internal structure of the 3D physical prototype, material types for the 3D physical prototype, and a surface finish for the 3D physical prototype, wherein the identifying the design is further based on the evaluated influencing factors.

4. The method of claim 2, further comprising:
identifying specific guidelines for manufacturing the 3D physical prototype, wherein the identifying the design is further based on the identified specific guidelines.

5. The method of claim 1, further comprising:
evaluating multiple manufacturing methods for manufacturing the 3D physical prototype, the manufacturing methods including material cutting, 3D printing, and casting; and
in response to the evaluating, selecting a manufacturing method included in the multiple manufacturing methods, wherein the creating the 3D physical prototype is further based on the selected manufacturing method.

6. The method of claim 1, further comprising:
designing, using the GenAI system, the physical prototype based on design criteria including minimizing a manufacturing time, reducing material costs, optimizing a weight distribution, and adjusting a center of gravity for the 3D physical prototype.

7. The method of claim 1, further comprising:
receiving consumer feedback about multiple features that are specified in different designs of the 3D physical prototype;
determining that a candidate design of the 3D physical prototype includes one or more features included in the multiple features;
based on the consumer feedback, determining one or more functionality importance scores for the one or more features, respectively;
determining that each of the one or more functionality importance scores exceeds a threshold value; and
generating and presenting a recommendation of the candidate design of the 3D physical prototype to be a final design of the 3D physical prototype based in part on each of the one or more functionality importance scores exceeding the threshold value.

8. A computer system comprising:
a processor set;
one or more computer-readable storage media; and
program instructions stored on the one or more computer-readable storage media to cause the processor set to perform computer operations comprising:
identifying historical data about designs of vehicles, the historical data including performance metrics and design parameters for digital and physical prototypes of the vehicles;
determining, by a processor set, an optimal distribution between using a digital prototyping and using a physical prototyping for a design of a vehicle by analyzing the identified historical data, the optimal distribution being based on functionality testing requirements for the design of the vehicle; and
creating, using a generative artificial intelligence (GenAI) system trained on the historical data, a three-dimensional (3D) physical prototype of the vehicle based on the optimal distribution.

9. The computer system of claim 8, wherein the computer operations further comprise:
identifying one or more first features of the vehicle that require testing using the physical prototyping and one or more second features of the vehicle that do not require testing using the physical prototyping; and
identifying, using the GenAI system, a design of the 3D physical prototype of the vehicle based on the identified one or more first features, wherein the design optimizes a usage of material and a manufacturing time in a process of manufacturing the 3D physical prototype, and wherein the creating the 3D physical prototype of the vehicle is further based on the identified design.

10. The computer system of claim 9, wherein the computer operations further comprise:
evaluating influencing factors for testing the 3D physical prototype, the influencing factors including a weight of the 3D physical prototype, an internal structure of the 3D physical prototype, material types for the 3D physical prototype, and a surface finish for the 3D physical prototype, wherein the identifying the design is further based on the evaluated influencing factors.

11. The computer system of claim 9, wherein the computer operations further comprise:
identifying specific guidelines for manufacturing the 3D physical prototype, wherein the identifying the design is further based on the identified specific guidelines.

12. The computer system of claim 8, wherein the computer operations further comprise:
evaluating multiple manufacturing methods for manufacturing the 3D physical prototype, the manufacturing methods including material cutting, 3D printing, and casting; and
in response to the evaluating, selecting a manufacturing method included in the multiple manufacturing methods, wherein the creating the 3D physical prototype is further based on the selected manufacturing method.

13. The computer system of claim 8, wherein the computer operations further comprise:
designing, using the GenAI system, the physical prototype based on design criteria including minimizing a manufacturing time, reducing material costs, optimizing a weight distribution, and adjusting a center of gravity for the 3D physical prototype.

14. The computer system of claim 8, wherein the computer operations further comprise:
receiving consumer feedback about multiple features that are specified in different designs of the 3D physical prototype;
determining that a candidate design of the 3D physical prototype includes one or more features included in the multiple features;
based on the consumer feedback, determining one or more functionality importance scores for the one or more features, respectively;
determining that each of the one or more functionality importance scores exceeds a threshold value; and
generating and presenting a recommendation of the candidate design of the 3D physical prototype to be a final design of the 3D physical prototype based in part on each of the one or more functionality importance scores exceeding the threshold value.

15. A computer program product comprising:
one or more computer-readable storage media; and
program instructions stored on the one or more computer-readable storage media to perform computer operations comprising:
identifying historical data about designs of vehicles, the historical data including performance metrics and design parameters for digital and physical prototypes of the vehicles;
determining, by a processor set, an optimal distribution between using a digital prototyping and using a physical prototyping for a design of a vehicle by analyzing the identified historical data, the optimal distribution being based on functionality testing requirements for the design of the vehicle; and
creating, using a generative artificial intelligence (GenAI) system trained on the historical data, a three-dimensional (3D) physical prototype of the vehicle based on the optimal distribution.

16. The computer program product of claim 15, wherein the computer operations further comprise:
identifying one or more first features of the vehicle that require testing using the physical prototyping and one or more second features of the vehicle that do not require testing using the physical prototyping; and
identifying, using the GenAI system, a design of the 3D physical prototype of the vehicle based on the identified one or more first features, wherein the design optimizes a usage of material and a manufacturing time in a process of manufacturing the 3D physical prototype, and wherein the creating the 3D physical prototype of the vehicle is further based on the identified design.

17. The computer program product of claim 16, wherein the computer operations further comprise:
evaluating influencing factors for testing the 3D physical prototype, the influencing factors including a weight of the 3D physical prototype, an internal structure of the 3D physical prototype, material types for the 3D physical prototype, and a surface finish for the 3D physical prototype, wherein the identifying the design is further based on the evaluated influencing factors.

18. The computer program product of claim 16, wherein the computer operations further comprise:
identifying specific guidelines for manufacturing the 3D physical prototype, wherein the identifying the design is further based on the identified specific guidelines.

19. The computer program product of claim 15, wherein the computer operations further comprise:
evaluating multiple manufacturing methods for manufacturing the 3D physical prototype, the manufacturing methods including material cutting, 3D printing, and casting; and
in response to the evaluating, selecting a manufacturing method included in the multiple manufacturing methods, wherein the creating the 3D physical prototype is further based on the selected manufacturing method.

20. The computer program product of claim 15, wherein the computer operations further comprise:
designing, using the GenAI system, the physical prototype based on design criteria including minimizing a manufacturing time, reducing material costs, optimizing a weight distribution, and adjusting a center of gravity for the 3D physical prototype.
